(19) United States
(12) Patent Application Publication
(10) Pub. No.: US 2026/0291409 A1
(43) Pub. Date: Sep. 24, 2026

(54) Methods of Electrostatic Clutch Sensorization and Performance Measurement

(71) Applicant: ESTAT Actuation, Inc., Pittsburgh, PA (US)

(72) Inventors: Stuart B. Diller, Pittsburgh, PA (US); Kirby A. Witte, Pittsburgh, PA (US); John D. Watkins, Pittsburgh, PA (US); William S. Lesso, Pittsburgh, PA (US)

(73) Assignee: ESTAT Actuation, Inc., Pittsburgh, PA (US)

(21) Appl. No.: 19/473,361

(22) PCT Filed: Apr. 8, 2024
(86) PCT No.: PCT/US2024/023648

§ 371 Date: Oct. 7, 2025

Related U.S. Application Data
(60) Provisional application No. 63/457,849, filed on Apr. 7, 2023.

(51) Int. Cl. H02N 13/00; G01L 1/22; G01R 19/10

(52) U.S. Cl. CPC H02N 13/00; G01L 1/2287; G01R 19/10

(57) ABSTRACT

A method of operating an electrostatic clutch uses data obtained from a controller, a separate measurement circuit, or a sensor to adjust operation of the clutch or to instruct a user to perform maintenance. The data can indicate various conditions within the clutch cause by long-term use, continuous use, electrode wear, and various other factors. Further, sensors can be incorporated into clutch members or the electrodes of the clutch for data acquisition. A combination of measurements can be useful in some cases to provide performance metrics not available with single measurement.

### CROSS-REFERENCE TO RELATED APPLICATIONS

This application claims the benefit under 35 U.S.C. § 119 of U.S. Provisional Application Ser. No. 63/457,849, filed on Apr. 7, 2023, which is incorporated herein by reference.

### STATEMENT REGARDING FEDERALLY SPONSORED RESEARCH

Not applicable.

### BACKGROUND OF THE INVENTION

The present disclosure generally relates to electrostatic clutches. More specifically, the disclosure relates to sensors and a method of using sensors to measure clutch performance.

Electroadhesion is a voltage driven phenomenon that does not require large current input of the magnitude required by conventional magnetic clutch solutions. This makes electrostatic clutches intrinsically more power efficient than current-driven electromagnetic devices for the same performance. They also do not require compressors and are simpler to implement than pneumatic or hydraulic solutions. In addition to being more power efficient, electrostatic clutches are also more compact because the electrodes can be incredibly thin as opposed to electromagnetic coils that are large and heavy with minimum sizes limited by resistive heating, wire gauge, and the number of loops.

An electrostatic clutch can have several functions including but not limited to: (1) limiting force applied to a load to prevent damage to the load; (2) limiting torque to protect components of a mechanical system; (3) limiting torque to an expected range to limit damage to items in the path of moving components or to limit damage to the moving components themselves; (4) limiting torque to prevent sudden increases in forces applied to a user or other load for safety reasons; (5) altering the connections within a drive train to adjust speed and maximum force output; and (6) establishing controllable, temporary connections as a fastener, lock, latch, or gripper with no moving parts.

Some solutions (i.e. traditional clutch and non-clutch systems) exist to provide these functions, but they fail to deliver high force accuracy and precision, lack the ability to be adjusted in real time electronically, are too bulky, or too power hungry to be effective in compact or mobile applications. Further, in many applications in which a clutch could provide benefits, designers opt for a use of a larger, more capable motor as opposed to a clutch and motor combination due to the weight, cost, complexity and power requirements associated with a clutch. In these cases, the motor performs all the tasks a clutch would perform.

In most cases, an electrostatic clutch could provide benefits over existing solutions in one or more of the following areas: improved precision and accuracy of force limitation, compactness, reduced overall weight, increased energy efficiency, improved controllability and responsiveness, reduced complexity and number of components, reduced heat production, and reduced cost. However, the properties of an electrostatic clutch can change as a function of the operating environment, short-term clutch activation history, and long-term clutch use. For example, wear of the dielectric material or electrode material can cause changes in the maximum holding force or torque. Additionally, the relationship between control parameters and clutch output properties can change over time. Therefore, it would be advantageous to implement methods of monitoring the clutch properties in order to make necessary or advantageous adjustments to the operation.

### BRIEF SUMMARY

This disclosure relates to methods used to measure electrostatic clutch properties, where the various measurements can be used to adjust and improve operation of the clutch. The electrostatic clutch properties that are measured may include capacitance, accumulated charge, leakage current, electrical shorts, charge and discharge time constant, voltage change, electrical impedance, electrical resistance, and space charge magnitude. Additional measurements can be made by incorporating sensors into the clutch structure, including strain gauges, piezoelectric sensors, capacitive encoders, inductive encoders, hall-effect sensors, eddy current sensors, shunt resistors, temperature sensors, humidity sensors, capacitive flex sensors and others.

These measurements can then be correlated to understand the status of clutch performance: including damage to the dielectric, electrodes, electrical connections, or structural components; hysteresis between applied voltage and torque or force output; clutch wear; clutch underperformance or overperformance; deformed shape of clutch components or attachment hardware; and intentional or unintentional clutch slip or rotation. This information is then used to adjust clutch behavior or the behavior of the greater mechanical system containing the clutch, compensate for changing clutch properties to maintain consistent performance, or indicate the need for preventative maintenance or replacement.

When discussed herein, an electrostatic clutch may comprise at least two electrodes separated by a dielectric material, where the electrodes are free to move relative to one another until a voltage is applied across the electrodes which causes them to adhere. These electrodes may be used to provide resistive forces in shear or normal directions or complex directions. FIG. 1 shows the configuration of the electrodes and dielectric material in a typical electrostatic clutch.

### BRIEF DESCRIPTION OF THE SEVERAL VIEWS OF THE DRAWINGS

FIG. 1 is a diagram showing the principle of electrostatic adhesion.

FIG. 2 is a block diagram of method, according to one embodiment.

FIG. 3 shows a method of charge integration.

FIGS. 4A-4B depict a capacitance method to monitor clutch wear.

FIGS. 5A-5B is a capacitance method to monitor clutch area.

FIGS. 6A-6B is a capacitance method to monitor contact.

FIGS. 7A-7B is a capacitance method and reference electrode hardware for monitoring clutch properties.

FIG. 8 is a patterned resistor in main clutch electrode body.

FIG. 9 is a patterned planar electrical features and off-the-shelf electrical components in clutch member.

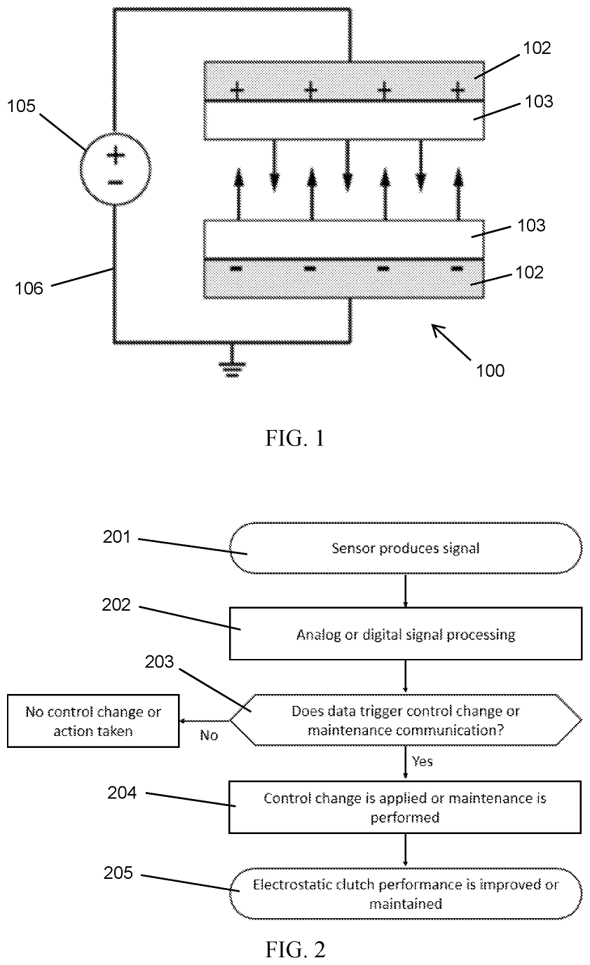

### DETAILED DESCRIPTION

According to embodiments is a clutch 100 comprising at least two electrodes 102 separated by a dielectric material 103. Activation of the clutch 100 depends on maintaining a voltage across the electrodes 102. This voltage can be applied using a circuit or controller 106 connected to an energy source 105. In addition to controlling the voltage, the circuit 106 can provide data about the clutch 100. In some embodiments, one or more sensors 110 can be included with the clutch 100 to provide additional data. Using the data, the performance of the clutch 100 can be adjusted due to the presence of certain factors affecting clutch performance.

For example, electrostatic clutch performance can vary depending on long-term use, recent use, operating conditions, damage, deflection, and other factors. Measured electrostatic clutch properties can be correlated to these factors and can communicate current and predicted performance. Therefore, it is a beneficial feature to a clutch user to have access to these measurements to adapt and implement improved control strategies, and to detect clutch failures or perform preventative maintenance. In many cases, the sensors 110 that enable these measurements can be directly incorporated into clutch members or electrodes 102, resulting in fewer components, reduced manufacturing and assembly costs, improved sensor readings, and/or improvements in inherent clutch safety.

For the purpose of concise description, “clutch member” is used throughout this document to describe a component or group of components capable of acting as an electrode 102 and transmitting a mechanical load resulting from electrostatic attraction. Some embodiments of clutch members are an electrode 102 alone, an electrode 102 with a flexible carrier, and a rigid substrate coated with a conductive layer acting as an electrode 102. Clutch members may include the dielectric material 103 in certain embodiments. Clutch members may be comprised solely by electrodes 102 capable of transmitting mechanical loads themselves as is the case in embodiments in which metal plates are used as both electrodes 102 and structural components. In other embodiments, clutch members comprising both electrodes 102 and reinforcing structural components may be used. Each clutch member is associated with an input or output of the clutch 100. At least two clutch members are required for an electrostatic clutch 100 to operate. For simplicity clutch members are often drawn as a single component in the figures. “Clutch interface” refers to the overlapping area of the input and output electrodes 102 over which a force of adhesion is established in the engaged state and may also refer to the opposing surfaces of the clutch members that contact one another.

FIG. 2 illustrates a method of controlling the operation of a clutch 100, according to one embodiment. Data from the sensors 110 are recorded, the measured signal (or data) is processed into actionable data for the user or control circuit 106, and the user or control circuit 106 takes some action or adjustment relative to the electrostatic clutch 100 based on the data. Referring again to FIG. 2, at step 201 data is acquired from the sensor 110. At step 202, the data undergoes analog or digital signal processing. Next, at step 203, it is determined whether the data triggers a control change or a maintenance communication. If there is no trigger, then no action is taken. If there is a trigger, then at step 204, the control change is applied to the operation of the clutch 100 or maintenance is performed. At step 205, the clutch 100 operates with improved performance as a result of the control change or the maintenance.

Examples of relevant data produced by the sensors 110 may include clutch capacitance, voltage, and leakage current. In these examples, the raw data could be correlated to an important clutch property or operating parameter using a predetermined model. For example, an increase in clutch capacitance could correlate to a higher slipping torque given a certain voltage input, or a sudden change in voltage may be correlated at a slip event, or the leakage current could be correlated to an advanced wear state of the dielectric layer 103.

Finally, these example correlations are used to change the controller 106 or user behavior, such as using the increase in clutch capacitance to initiate a reduction in operating voltage to achieve the desired slipping torque, or using the knowledge of an advanced wear state to send a “maintenance needed” indication to the user. This model would be generated either with test samples representative of a certain design or combination of clutch materials, or with the individual clutches 100 themselves during quality control or during operation. In another embodiment, a predetermined model of clutch properties is not required, and changes in sensor data or the case of sensor data falling outside a set of control boundaries indicates a change in performance or triggers an action by the control circuit 106.

In the following section, examples of specific sensors 110, measurement methods, and clutch properties correlations will be discussed.

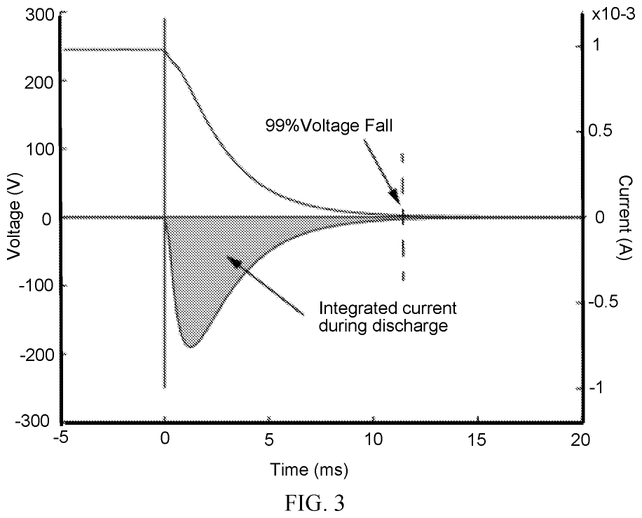

Clutch capacitance correlates to the maximum slipping force or torque, to the clutch wear state, and to changes in the electrode or dielectric properties that lead to damage or loss of operation. Capacitance is measured in a variety of ways, including during active clutch operation. Methods include the charge integration method during constant resistance charging or discharging, the charge integration method during constant current charging or discharging, the voltage time derivative method during constant current charging or discharging, the charge sharing method with a reference capacitor, the charge time method to determine the RC time constant with a known series resistance, the self-resonant frequency measurement method with a known inductance, or the phase shift method. Measured capacitance is correlated with clutch properties using equation (2) and/or by using empirical datasets. As an example, the constant resistance charge integration method is illustrated in FIG. 3, which is a graph depicting voltage and current vs time.

$$C = \frac{ε {ε}_{0} A}{d} \qquad EQ . ( 2 )$$

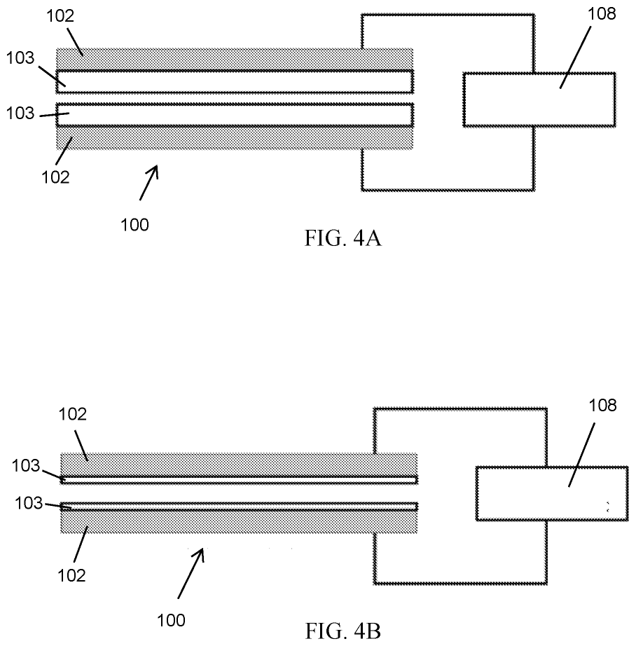

In this equation, C is measured capacitance, ε is the effective dielectric constant of the dielectric layer 103, ε₀ is the electric constant, A is the clutch overlap area, and d is the effective dielectric thickness. In cases where the clutch overlap area is reliably known (FIG. 4A), changes in capacitance can be correlated to changes in the effective dielectric thickness such as wear of the dielectric layer 103 (FIG. 4B) or changes in the surface properties or wear interface. Because capacitance increase as dielectric thickness decreases, wear of the dielectric layer may be detected by observing an increase in capacitance.

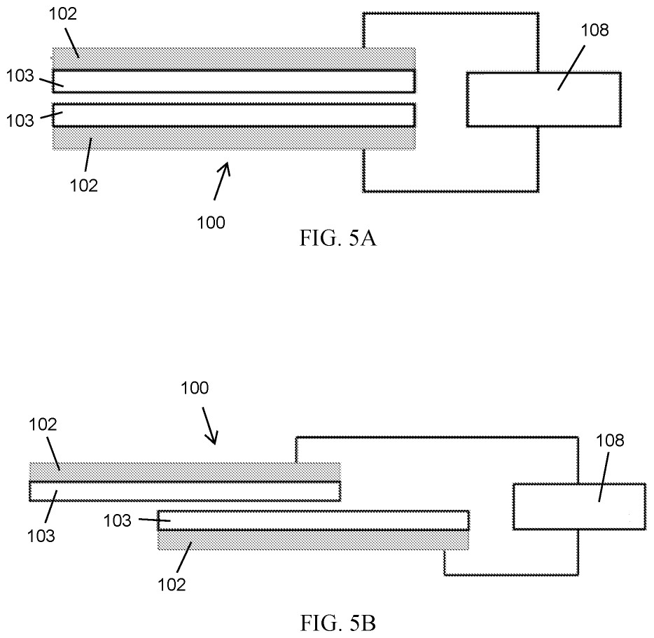

In other cases where the effective dielectric thickness is well known, such as a surface clutch interacting with a known substrate, a change in clutch capacitance can indicate a change in the clutch overlap area with the substrate (FIGS. 5A-5B). Because capacitance is correlated to overlapping electrode area, the capacitance reading may be used to infer the total overlapping electrode area. In FIG. 5A, a high overlap area correlates to a higher capacitance. In FIG. 5B, a low overlap area correlates to a lower capacitance.

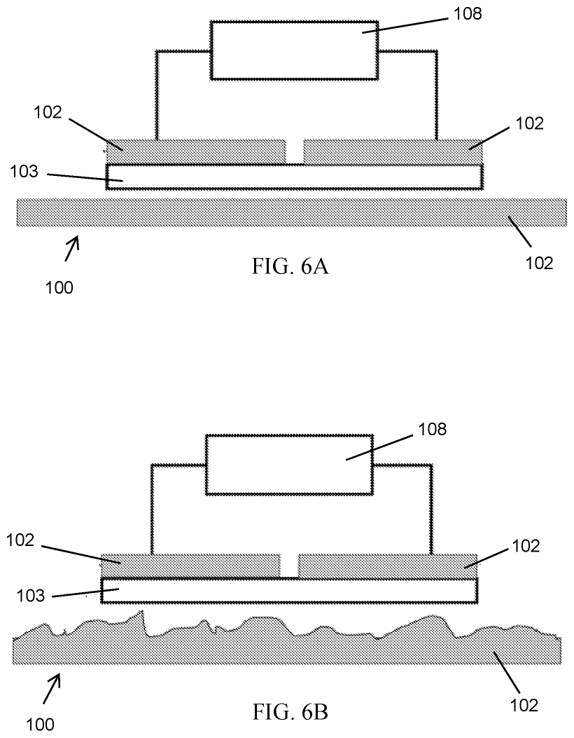

Alternatively, if clutch area is separately measured or known, a measure of clutch capacitance can correlate to the ‘goodness’ of a connection of the surface clutch to the substrate and the expected maximum interface force (FIGS. 6A-6B). Because high surface roughness causes a greater distance between electrodes, higher surface roughness leads to lower capacitance. This measure can also identify unknown substrates that have various surface properties. These measures can be made relative to a known baseline model or in reference to prior known operation data. In FIG. 6A, good contact leads to higher capacitance, whereas the poor contact in FIG. 6B leads to a lower capacitance.

Clutch 100 charge/discharge time can be measured by observing the voltage and current during activation and deactivation. This metric correlates to the mechanical engage and disengage times of the clutch 100. Observing this metric could enable controller 106 changes in use cases where a particular mechanical engage and disengage behavior is desired in the overall machine operation into which the clutch 100 is incorporated.

Measuring multiple clutch properties simultaneously can provide much greater levels of insight. For example, observing an increase in clutch 100 charge/discharge times while overall capacitance does not change could correspond to an unexpected increase in series resistance in the clutch 100 charging/discharging circuit 106 and indicate a failing electrical connection. This could then be indicated to the user for preventative maintenance. While observing only one signal or the other, this conclusion would be difficult to reach.

The leakage current of the electrostatic clutch 100 is measured during the activated clutch state (i.e. attraction between opposing electrodes 102), and changes in leakage current can correlate to changes in the effective thickness of the dielectric material 103 separating the electrodes 102. Monitoring current while the clutch 100 is activated can also be useful for detecting electrical shorts or breakdown of the dielectric material 103. The clutch complex impedance can also be measured to identify whether current pathways through the electrode and electrical connections are changing over time, which may be an indication of damage to the clutch 100. The leakage current can be measured in a variety of ways, including by measuring voltage across a shunt resistor using a microcontroller or data recorder, which can be integrated into the controller 106.

In cases where multiple sets of clutch electrodes 102 are used together in series, forming a stack of electrodes 102, such that the total applied voltage across the stack is split between multiple clutch interfaces, the voltage drop across each set can be measured to evaluate any damage to the individual sets (i.e. a pair of adjacent electrodes 102) and the overall clutch 100. If one set has an unintended larger voltage drop across it, the force or torque at that interface could exceed the intended value while the force or torque at the other interfaces could underperform. Because many implementations of multiple clutch electrodes 102 in series are designed to eliminate direct electrical connections to some electrodes 102 during operation, this measurement could take place in a charging dock, protective holder, or external electrical evaluation station designed to connect to each electrode 102 or evaluate the electrode sets individually.

In some embodiments, the capacitance, charge/discharge time, leakage current, and voltage drop measurements could be performed by a portion of the controller 106, the primary activation circuit, during operation. The primary activation circuit is defined as the part of the circuit 106 that supplies voltage to the clutch 100 to control activation, deactivation, and other behavior during normal operation. In other embodiments, these measurements may be performed by the primary activation circuit 106 when the clutch 100 is not being operated, as a dedicated clutch 100 monitoring action. In some embodiments, the capacitance, charge/discharge time, leakage current, and voltage drop measurements could be performed by a circuit 108 separate from the primary activation circuit 106. This circuit 108 could be integral to the clutch 100 itself, or a part of an external interface that the clutch 100 connects to for routine or spot-check monitoring/maintenance, or for storage, battery charging, or protection. In any of these embodiments, the measurement circuit 106/108 may also include a microcontroller, sensor components, ADC, or other electrical components to facilitate easy analog or digital communication of information.

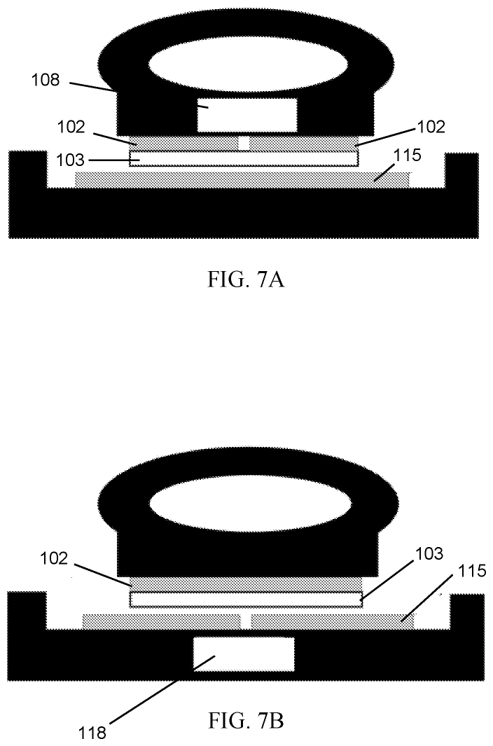

FIGS. 7A-7B show the measurement of clutch capacitance vs. a well-known reference electrode 115 in a protective storage and maintenance base where the capacitance measurement circuit electronics are located in the surface clutch handler (FIG. 7A) and the capacitance measurement circuit electronics are located in the base (FIG. 7B).

Off-the-shelf sensors 110 and components may be incorporated into the electrostatic clutch 100 to perform other measurements. These include encoders 110 to measure position, velocity, and acceleration, piezoelectric sensors 110 or accelerometers 110 to detect vibration, thermal sensors 110 to detect temperature, hall effect and eddy current sensors 110 to detect magnetic fields, light sensors 110 to measure clutch member and clutch interface opacity, strain gauges 110 to measure force or torque, and others. These sensors 110 can be adhered, cast into, laminated, or otherwise connected to clutch members. They can also be placed into or on other structural or support components, such as shafts, housings, bearings, PCB hardware, adhesive layers or other fasteners, and other components of the clutch 100. In some embodiments, signal sources such as piezoelectric actuators, heaters, or LEDs may also be placed into the clutch 100 to generate a signal that is altered by the components of the clutch 100 or behavior thus generating a feedback signal, which is then measured by the appropriate sensor 110.

In some embodiments, sensors 110, signal sources, or electrical components 111 may be created integrally in the clutch members or components during the manufacturing process. For example, during patterning of the electrostatic clutch electrode 102, a resistor 111 could be patterned between the main body 121 of the electrode 102 and the electrical connection 122. Making these components integral to the clutch members reduces the number of components, simplifies manufacturing and assembly, reduces costs, improves sensor readings, improves clutch performance by reducing flexural rigidity of clutch members, and enhances clutch safety features.

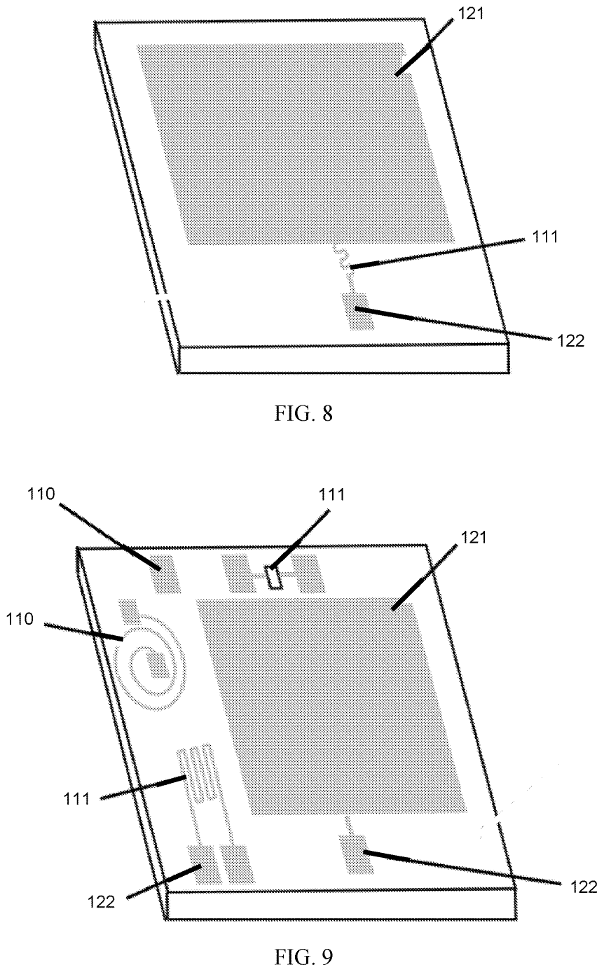

In one embodiment, an electrical resistor (i.e. electrical component 111) is patterned into the clutch electrode 102 in series between the main electrode body 121 and the electrical connection 122 to the voltage driver or energy source 105 (FIG. 8). By tuning the geometry and resistance value of the resistor 111, it could be used as an electrical fuse to prevent extended over-current to a particular set of electrodes 102 to enhance safety and prevent damage, or as a means to slow the electrical charge/discharge time under normal use to a more easily measured value.

In another embodiment, an electrical resistor 111 is patterned into the clutch electrode 102 alongside the main electrode body 121, and is connected to a separate measurement circuit 108 (FIG. 9). This resistor could measure wear of the electrode layer 102 because the loss of material on the top surface would cause a measurable increase in resistance. Alternatively, the resistor 111 could be patterned in the shape of a strain gauge 111 and produce a measurable change in resistance in response to mechanical deformation of the clutch member.

In another embodiment, an electrical resistor 111 is patterned into the clutch electrode 102 alongside the main electrode body 121, and is connected to a circuit 108 to act as a resistive heater. The heater could be used to generate a signal that is then altered by a measurable clutch property such as the presence of electrical charge in the dielectric material 103, and then measured by a thermocouple or other temperature sensor. In some embodiments the heater could be used to maintain an optimal performance temperature for the clutch 100 or prevent clutch components from being damaged in a cold operating environment.

In another embodiment, measurements of capacitance across the clutch interface can be used to intuit the degree of travel experienced by the clutch 100. The capacitance of the clutch interface is proportional to the overlap area of the clutch electrodes 102. In some clutch embodiments, this overlap area may change with extension or rotation of the clutch 100.

In another embodiment, flex or stretch sensors 110 can be patterned into the clutch members. A pattern of exposed electrodes 102 can be disposed on the surfaces of multiple clutch members and separated by dielectric material 103. As the clutch members bend, the alignment of these electrodes 102 changes, which changes their overlap area and therefore their capacitance (or resistance). If the locations of these electrodes 102 are known as well as the thickness of the clutch member and the gap between them, the degree of bend can be calculated from the capacitance measurement. Other electrical features may also be patterned into the clutch member, such as coils, pads, and any other features 111 that can be patterned into thin flexible layers, in addition to placement of off-the-shelf components that are compatible with flexible members, such as those commonly found in flexPCB designs (FIG. 9). The components or features 111 shown in FIG. 9 may also exist on multiple layers of the clutch member.

In some embodiments, small electrode patches 111 may be patterned into the clutch member, for example to be used in a capacitance-based encoder, contact-resistance based encoder, or resolver. In other embodiments, planar spiral coils 111 may be patterned into the clutch member to either measure or produce a magnetic field. These off-the-shelf and patterned electrical components may be a part of the clutch activation circuit 106 or a separate measurement circuit 108. The clutch member may have multiple layers and vias to accommodate multiple electrostatic clutch electrodes 102, flexible circuits, and integrated sensors 110. The patterned electrical features 111 may connect to a measurement circuit 108 or a voltage driver circuit 106 using any removable or permanent electrical connector.

In another embodiment, multiple clutch members are each instrumented with a sensor 110 and separately monitored. This may be all of the clutch members, or a subset of them. In this embodiment, multiple modular clutch units that contain clutch members are assembled into a single electroadhesive clutch 100. The advantage to reading sensor readings from multiple clutch members is that a more accurate state of clutch performance or health may be observed. For example, force sensors 110 integrated into each clutch member could indicate whether some clutch members are being overloaded or underloaded. In another example, measuring the capacitance of multiple clutch members could indicate if and where an electrical connection has been lost.

In one embodiment, the clutch control circuit 106 adapts its properties in response to a sensor signal from the clutch 100. For example, the clutch control circuit 106 may increase or decrease the switching frequency of a voltage boosting circuit of the controller 106 in response to the measured capacitance of the electrostatic clutch 100. This allows the circuit 106 to correctly achieve the allowable voltage ripple while minimizing the power consumption, heat generation, and electromagnetic emissions from the circuit 106. This further allows a single circuit design to operate a range of electrostatic clutches 100 with different capacitances, or a single electrostatic clutch 100 whose capacitance changes during the course of normal use.

Any of the measurements mentioned herein or combination of these measurements may be performed continuously, intermittently on a schedule, upon start up, upon shut down, or upon connection to a charge station, maintenance dock, or other case or stand. These measurements may also be performed during regular maintenance checks during which the user is instructed to perform specific actions to aid the effectiveness of the measurement.

When used in this specification and claims, the terms “comprises” and “comprising” and variations thereof mean that the specified features, steps, or integers are included. The terms are not to be interpreted to exclude the presence of other features, steps or components.

The invention may also broadly consist in the parts, elements, steps, examples and/or features referred to or indicated in the specification individually or collectively in any and all combinations of two or more said parts, elements, steps, examples and/or features. In particular, one or more features in any of the embodiments described herein may be combined with one or more features from any other embodiment(s) described herein.

Protection may be sought for any features disclosed in any one or more published documents referenced herein in combination with the present disclosure. Although certain example embodiments of the invention have been described, the scope of the appended claims is not intended to be limited solely to these embodiments. The claims are to be construed literally, purposively, and/or to encompass equivalents.

What is claimed is:

1. A method of measuring properties of an electroadhesive clutch having electrodes or clutch members and a dielectric, the method comprising:
measuring data related to a property of the clutch; and
adjusting clutch performance or use using the data.

2. The method of claim 1, where the data comprises an electrical charge stored in the electrodes upon activation, during activation, upon deactivation, or upon contact/disconnect from a substrate or an opposing electrode, wherein the electrical charge causes a change in capacitance or resistance.

3. The method of claim 2, wherein the electrical charge is measured using a charge integration method during constant resistance charging or discharging, the charge integration method during constant current charging or discharging, a charge sharing method with a reference capacitor, a charge time method to determine an RC time constant with a known series resistance, or a phase shift method.

4. The method of claim 1, wherein the data comprises at least one of an instantaneous or average electrical current passing through the clutch, a voltage across the electrodes, a complex impedance of the clutch, a force or torque experienced by the clutch, a position, travel, speed, or acceleration of the clutch, a transparency of the clutch members and a clutch interface, a vibration of a clutch member, and a temperature of a clutch member.

5.-9. (canceled)

10. The method of claim 1, wherein the data comprises a resistance of a patterned resistor at a wear interface of the clutch using an applied voltage separate from a voltage used to control clutch activation/deactivation.

11.-12. (canceled)

13. The method of claim 1, wherein the data is measured during battery charging, downtime, or some other time when the clutch is inactive.

14. The method of claim 13, wherein the data is measured using an apparatus external to the clutch, wherein the apparatus is incorporated into a charging dock, protective holder, or diagnostic instrument.

15. The method of claim 1, wherein adjusting clutch performance or use comprises changing an applied voltage to the clutch.

16. The method of claim 1, wherein adjusting clutch performance or use comprises providing an indication of remaining clutch life.

17. The method of claim 1, wherein adjusting clutch performance or use comprises providing an indication of clutch damage.

18. The method of claim 1, wherein adjusting clutch performance or use comprises changing electrical properties of a control circuit.

19. The method of claim 1, wherein adjusting clutch performance or use comprises adjusting a timing or control of clutch behavior.

20. The method of claim 1, wherein adjusting clutch performance or use comprises halting, releasing, or altering a behavior of a greater mechanical system containing the clutch.

21. The method of claim 2, further comprising correlating the charge to an interface contact area, to a location of interface contact area on the electrode or across multiple electrodes, or to an electrical or physical property of the clutch members or a substrate.

22. The method of claim 1, wherein the data is measured on multiple modules or subsystems within the clutch, or on some subset of the clutch members.

23. The method of claim 18, further comprising adjusting a switching frequency of the control circuit based on a measured capacitance of the clutch.

24. The method of claim 1, further comprising:
using a controller, receiving the data, analyzing the data, and controlling operation of the clutch; and
providing a separate measurement circuit connected to a sensor.

25. A method of fabricating an electrostatic clutch having a clutch member comprising:
incorporating a sensor or electrical component directly into the electrostatic clutch member.

26. The method of claim 25, wherein the sensor is at least one of a strain gauge, a piezoelectric sensor, a capacitive encoder, a magnetic field sensor, a temperature sensor, an inductive encoder, and a light sensor.

27. The method of claim 25, wherein the electrical component is a resistor.

28.-32. (canceled)

33. The method of claim 26, wherein the sensor is a strain gauge which is patterned into the clutch member or an electrode of the clutch member.

34.-43. (canceled)
